(19) United States
(12) Patent Application Publication
(10) Pub. No.: US 2014/0203335 A1
(43) Pub. Date: Jul. 24, 2014

(54) Semiconductor Devices and Methods for Fabricating the Same

(71) Applicant: Samsung Electronics Co., Ltd., Suwon-si (KR)

(72) Inventors: Jae-Yeol Song, Seoul (KR); June-Hee Lee, Hwaseong-si (KR); Hye-Lan Lee, Hwaseong-si (KR); Sang-Jin Hyun, Suwon-si (KR); Sang-Bom Kang, Seoul (KR)

(73) Assignee: Samsung Electronics Co., Ltd., Suwon-si (KR)

(21) Appl. No.: 14/155,579

(22) Filed: Jan. 15, 2014

(30) Foreign Application Priority Data
Jan. 22, 2013 (KR) 10-2013-0007048

(51) Int. Cl. H01L 29/78; H01L 21/28

(52) U.S. Cl. CPC H01L 29/78; H01L 21/28158
USPC 257/288; 438/591

(57) ABSTRACT

A semiconductor device includes an insulating film on a substrate and including a trench, a gate insulating film in the trench, a DIT (Density of Interface Trap) improvement film on the gate insulating film to improve a DIT of the substrate, and a first conductivity type work function adjustment film on the DIT improvement film. Related methods of forming semiconductor devices are also disclosed.

### CROSS-REFERENCE TO RELATED APPLICATION

This application is based on and claims priority from Korean Patent Application No. 10-2013-0007048, filed on Jan. 22, 2013 in the Korean Intellectual Property Office, the disclosure of which is incorporated herein in its entirety by reference.

### FIELD

The present invention relates to semiconductor devices and methods for fabricating the same.

### BACKGROUND

As the feature size of metal oxide semiconductor (MOS) transistors is decreased, the gate length and channel length of the transistors is reduced. However, reduction of gate and channel lengths can be problematic for MOS transistor operation. Moreover, there is interest in increasing the capacitance between the gate and the channel and in otherwise improving the operational characteristics of MOS transistors.

### SUMMARY

According to some embodiments of the present inventive concept, there is provided a semiconductor device including an insulating film on a substrate and including a trench, a gate insulating film in the trench, a DIT (Density of Interface Trap) improvement film on the gate insulating film to improve a DIT of the substrate, and a first conductivity type work function adjustment film on the DIT improvement film.

According to further embodiments of the present inventive concept, a method for fabricating a semiconductor device includes forming an interlayer insulating film that includes first and second trenches on a substrate, forming a gate insulating film in the first and second trenches, forming a DIT improvement film that improves a DIT of the substrate on the gate insulating film, and forming a first conductivity type work function adjustment film on the DIT improvement film.

### BRIEF DESCRIPTION OF THE DRAWINGS

The above and other objects, features and advantages of the present invention will be more apparent from the following detailed description taken in conjunction with the accompanying drawings, in which:

FIG. 1 is a cross-sectional view of a semiconductor device according to a first embodiment of the present invention;

FIG. 2 is a graph illustrating an effective work function (EWF) in accordance with the thickness of the DIT improvement film 60 in a P-type transistor;

FIG. 3 is a graph illustrating the change of a DIT of a P-type transistor, which is effected by the DIT improvement film;

FIG. 4 is a cross-sectional view of a semiconductor device according to a second embodiment of the present invention.

FIG. 5 is a flowchart of a method for fabricating a semiconductor device according to an embodiment of the present invention;

FIGS. 6 to 12 are views of intermediate steps explaining the flowchart of FIG. 5;

FIGS. 13 to 17 are views of intermediate steps explaining a method for fabricating a semiconductor device according to the second embodiment of the present invention;

FIG. 18 is a view explaining a semiconductor device according to a third embodiment of the present invention;

FIG. 19 is a cross-sectional view cut along line A-A′ in FIG. 18;

FIG. 20 is a cross-sectional view cut along line B-B′ in FIG. 18;

FIGS. 21 and 22 are a circuit diagram and a layout diagram explaining a semiconductor device according to a fourth embodiment of the present invention;

FIG. 23 is a view explaining a semiconductor device according to a fifth embodiment of the present invention;

FIG. 24 is a block diagram of an electronic system including a semiconductor device according to some embodiments of the present invention; and

FIGS. 25 and 26 are exemplary views of a semiconductor system to which the semiconductor device according to some embodiments of the present invention can be applied.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified.

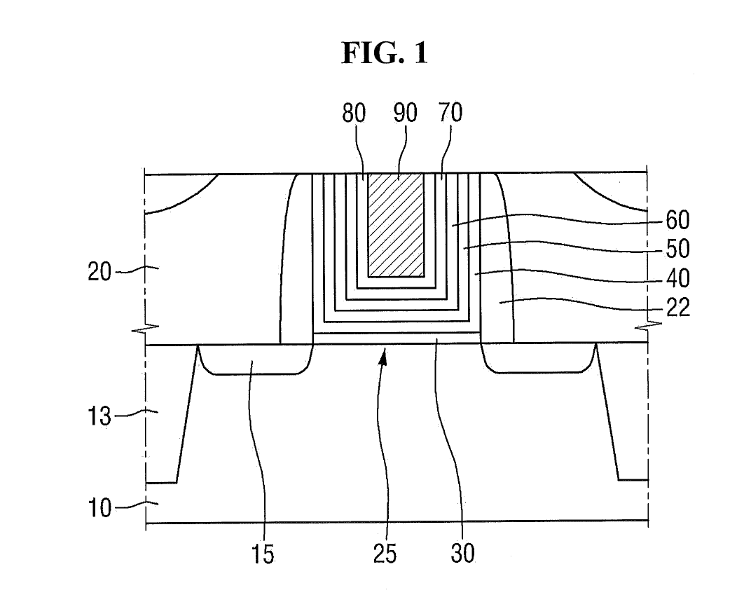

Referring to FIG. 1, a semiconductor device according to some embodiments of the present invention will be described.

FIG. 1 is a cross-sectional view of a semiconductor device according to some embodiment of the present invention.

Referring to FIG. 1, a semiconductor device may include a substrate 10, an interlayer insulating film 20 including a trench 25, an interface film 30 formed inside the trench 25, a gate insulating film 40, an etching prevention film 50, a DIT improvement film 60, a first conductivity type work function adjustment film 70, a second conductivity type work function adjustment film 80, and a gate metal 90.

An isolation film 13, such as STI (Shallow Trench Isolation), is formed in the substrate 10 to define an active region. The substrate 10 may include one or more semiconductor materials selected from the group consisting of, for example, Si, Ge, SiGe, GaP, GaAs, SiC, SiGeC, InAs, and InP, a rigid substrate, such as a SOI (Silicon On Insulator) substrate, a quartz substrate, or a glass substrate for display, or a flexible plastic substrate made of polyimide, polyethylene terephthalate (PET), polyethylene naphthalate (PEN), poly methyl methacrylate (PMMA), polycarbonate (PC), polyethersulfone (PES), or polyester.

The interlayer insulating film 20 may be formed on the substrate 10 and may include the trench 25 therein. The interlayer insulating film 20 may be formed by stacking two or more insulating films. As illustrated, a spacer 22 may be formed on a side wall of the trench 25, and the substrate 10 may be disposed on a bottom surface of the trench, but they are not limited thereto. The spacer 22 may include at least one of a nitride film and an oxynitride film. Further, the spacer 22 may be formed in an “L” shape, unlike the illustrated shape. In the drawing, the spacer 22 is illustrated as a single layer, but is not limited thereto. The spacer 22 may, for example, be formed as a multilayer film.

The interface film 30 may serve to improve an interface between the semiconductor substrate 10 and the gate insulating film 40. The interface film 30 may include a low-k material layer having a dielectric constant k that is equal to or lower than nine (9). For example, the interface film 30 may be a silicon oxide film (which has a k of approximately 4) or a silicon oxynitride film (which has a k of approximately 4 to 8 depending on the relative concentrations of oxygen atoms and nitrogen atoms in the film). Further, the interface film 30 may be made of silicate, or may be made of a combination of the above exemplified films.

The interface film 30 may be formed, for example, in a thermal oxidation process, but is not limited thereto.

The gate insulating film 40 may be conformally formed along the side wall and the bottom surface of the trench 25. The gate insulating film 40 may include a high-k material having higher dielectric constant than silicon oxide. That is, the gate insulating film 40 may be a high-k material film. For example, the gate insulating film 40 may include a material selected from the group consisting of HfSiON, HFO₂, ZrO₂, Ta₂O₅, TiO₂, SrTiO₃, and (Ba,Sr)TiO₃. The gate insulating film 40 may be formed with a thickness that is selected based on the kind of device that is to be formed.

The etching prevention film 50 may be formed on the gate insulating film 40 in the trench 25. As illustrated, the etching prevention film 50 may be conformally formed along the side wall and the bottom surface of the trench 25. The etching prevention film 50 may include, for example, at least one of Ti, Ta, W, Ni, Nb, Mo, Hf, La, nitride, carbide, and silicide, but is not limited thereto.

The etching prevention film 50 may be used to protect the gate insulating film 40 when the first and second conductivity type work function adjustment films 70 and 80, which are formed in different regions, are etched. This will be described later.

In FIG. 1, the etching prevention film 50 is illustrated as one film. However, the etching prevention film 50 may be formed as a plurality of films.

The DIT improvement film 60 may be formed on the etching prevention film 50 in the trench, and may be conformally formed along the side wall and the bottom surface of the trench 25. The DIT improvement film 60 may be an Al alloy film. For example, the DIT improvement film 60 may be a film that includes at least one of Ti, Ta, W, Ni, Nb, Mo, Hf, and La together with Al, and may also include carbon, for example, TaAlC or the like.

The first conductivity type work function adjustment film 70 may be formed on the DIT improvement film 60 in the trench 25. Specifically, the first conductivity type work function adjustment film 70 may be conformally formed along the side wall and the bottom surface of the trench 25. Specifically, the first conductivity type may be P-type. The first conductivity type work function adjustment film 70 serves to adjust the operating characteristics of a P-type transistor through adjustment of a work function of the transistor. The first conductivity type work function adjustment film 70 may include, for example, at least one of Mo, Pd, Ru, Pt, TiN, WN, TaN, Ir, TaC, RuN, and MoN.

The second conductivity type work function adjustment film 80 may be formed on the first conductivity type work function adjustment film 70 in the trench 25. Specifically, the second conductivity type work function adjustment film 80 may be conformally formed along the side wall and the bottom surface of the trench 25. The second conductivity type is different from the first conductivity type. For example, the second conductivity type may be N-type. The second conductivity type work function adjustment film 80 serves to adjust the operation characteristics of an N-type transistor through adjustment of a work function of the transistor. The second conductivity type work function adjustment film 80 may include, for example, TiAl or TiAlN. In particular, the second conductivity type work function adjustment film 80 may include the same material as the material that the DIT improvement film 60 includes such as, for example, Al.

If the first conductivity type work function adjustment film 70 is below the second conductivity type work function adjustment film 80, then even though the second conductivity type work function adjustment film 80 is formed on the first conductivity type work function adjustment film 70, the first conductivity type work function adjustment film 70 exerts an influence on the operational characteristics of the transistor. However, the second conductivity type work function adjustment film 80 cannot exert an influence on the operational characteristics of the transistor. As a result, only the first conductivity type work function adjustment film 70 can adjust the operational characteristics of the transistor. Accordingly, if the first conductivity type work function adjustment film 70 (P-type) is below the second conductivity type work function adjustment film 80 (N-type), the semiconductor device illustrated in FIG. 1 operates as a P-type transistor.

The gate metal 90 may be formed on the second conductivity type work function adjustment film 80 in the trench 25, and may fill the trench 25. The gate metal 90 may include, for example, Al, W, and the like, but is not limited thereto.

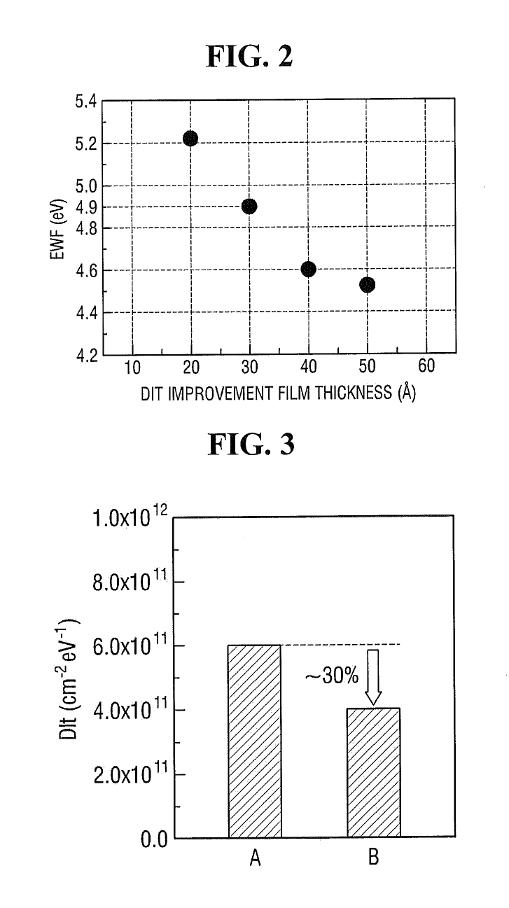

Referring to FIGS. 2 and 3, effects of the semiconductor device according to the present invention will be described. FIG. 2 is a graph illustrating an effective work function (EWF) as a function of the thickness of the DIT improvement film 60 in a P-type transistor, and FIG. 3 is a graph illustrating the change of a DIT of a P-type transistor, which is effected by the DIT improvement film.

The DIT improvement film 60 may be an Al alloy film. Al is a material that exerts an influence on the operational characteristics of an N-type transistor, and Al is typically not used in a P-type transistor. If Al is used in a P-type transistor, it may exert an influence on the work function of the P-type transistor to deteriorate a threshold voltage Vt, and as a result, it may deteriorate the performance of the semiconductor device.

Referring to FIG. 2, the Y-axis represents an EWF, and the X-axis represents the thickness of the DIT improvement film 60. Here, the DIT improvement film 60 includes TaAlC. According to the graph, it can be confirmed that the EWF is decreased as the DIT improvement film 60 becomes thicker. In order for a P-type transistor to operate normally, it is generally desirable for the EWF to be at least equal to or higher than 4.9 eV, and the DIT improvement film 60 must therefore have a thickness that is equal to or smaller than 30 Å. Further, in order to reduce the DIT, the DIT improvement film 60 must have a thickness that is at least equal to or greater than 1 Å.

FIG. 3 is a graph illustrating a DIT improvement effect in the case where the DIT improvement film 60 is disposed. The Y-axis represents a DIT between the substrate 10 and the interface film 30. On the X-axis, ‘A’ denotes a P-type transistor in which the DIT improvement film 60 is not formed, and ‘B’ denotes a P-type transistor in which the DIT improvement film 60 is present. In this experiment, the DIT improvement film 60 includes TaAlC.

Referring to FIG. 3, the DIT in the case where the DIT improvement film 60 is not formed is 6.0×10¹¹ (cm⁻² eV⁻¹), whereas the DIT in the case where the DIT improvement film 60 is present is 4.0×10¹¹ (cm⁻² eV⁻¹), which can be confirmed as about 30% decrease of the DIT. If the DIT is decreased, the number of carriers (electrons or holes) passing through a channel region, which are trapped by defects occurring on the interface, is decreased. This may increase mobility of carriers in the channel, and thus improve the performance of the P-type transistor. As a result, if the DIT improvement film 60 is formed, the performance of the semiconductor device can be improved.

On the other hand, in order for the DIT improvement film 60 to improve the DIT between the substrate 10 and the interface film 30, it is desirable for the distance between the DIT improvement film 60 and the substrate 10 to be short. Accordingly, it is desirable to form the etching prevention film 50 to be formed as thin as possible, for example, the thickness of the etching prevention film 50 may be equal to or smaller than 30 Å. In order to reduce the etching of the gate insulating film 40, the etching prevention film 50 may have a thickness that is at least equal to or larger than 1 Å.

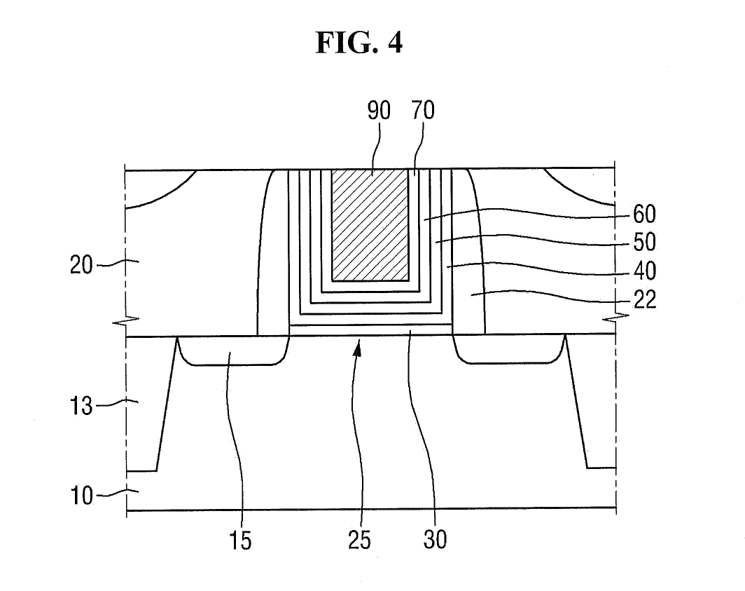

Referring to FIG. 4, a semiconductor device according to further embodiments of the present invention is illustrated. Some features and aspects of the semiconductor device of FIG. 4 are similar to those of the semiconductor device FIG. 1, and will not be described again for brevity.

Unlike the semiconductor device illustrated in FIG. 1, the semiconductor device illustrated in FIG. 4 does not include a second conductivity type work function adjustment film (80 in FIG. 1). This difference is caused by the difference between methods for fabricating semiconductor devices according to embodiments of the present invention, and will be described later. The existence/nonexistence of the second conductivity type work function adjustment film (80 in FIG. 1) does not exert an influence on the performance of the semiconductor devices according to embodiments of the present invention.

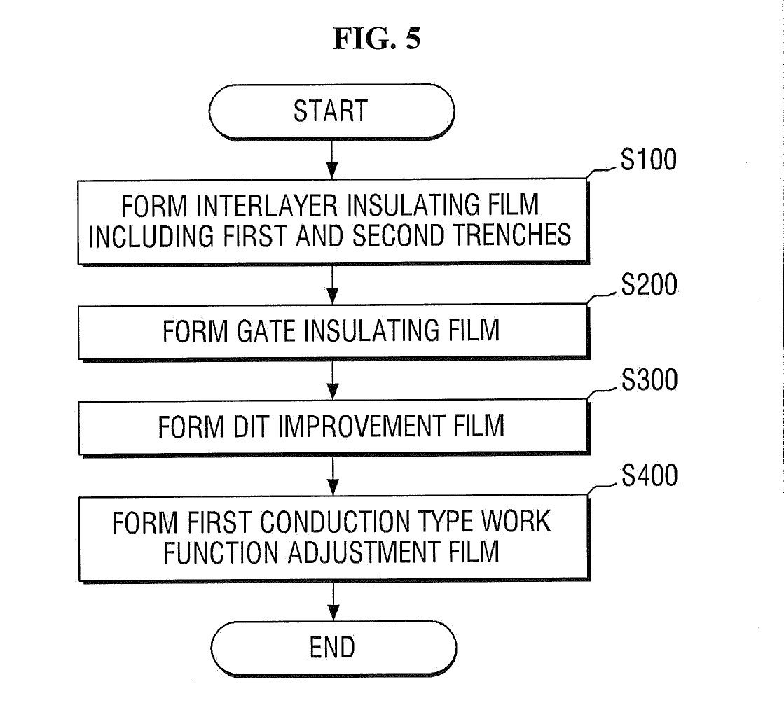

Referring to FIGS. 5 to 12, methods of forming a semiconductor device according some embodiments of the present invention will be described.

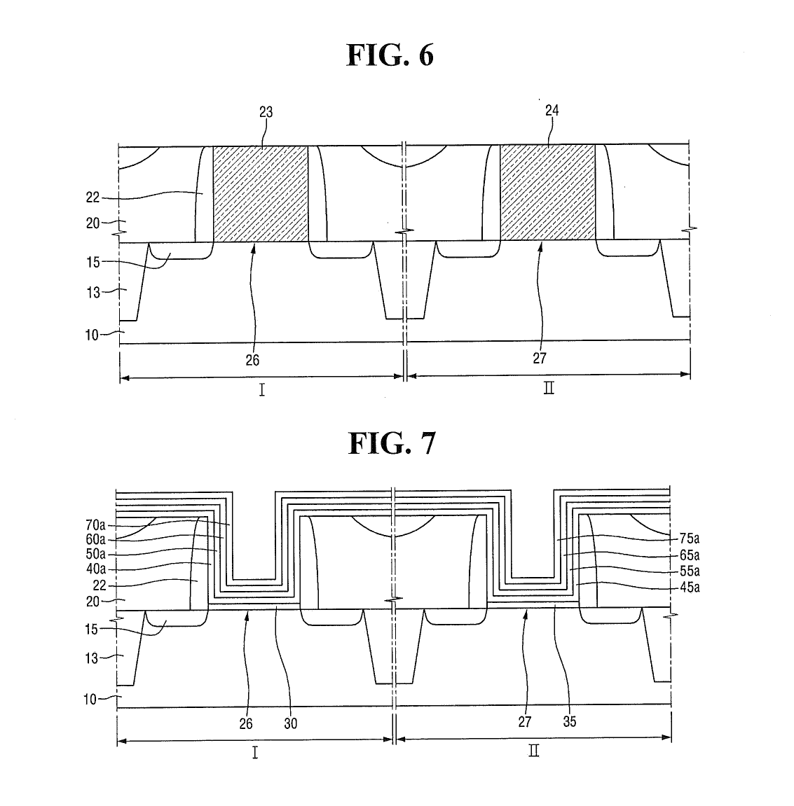

FIG. 5 is a flowchart illustrating operations for forming a semiconductor device according to some embodiments of the present invention. FIGS. 6 to 12 are views of intermediate steps illustrating various operations in the flowchart of FIG. 5.

First, referring to FIGS. 5 and 6, an interlayer insulating film 20 that includes first and second trenches 26 and 27 is formed on a substrate 10 (S100).

The substrate 10 includes a first region I and a second region II, which may be separated from each other by an isolation film 13. For example, a PMOS transistor may be formed on the first region I of the substrate 10, and an NMOS transistor may be formed on the second region II of the substrate 10. However, the present invention is not limited thereto.

A first sacrificial gate 23 is formed on the first region I, and a first spacer 22 is formed on a side wall of the first sacrificial gate 23. The interlayer insulating film 20 surrounds the first sacrificial gate 23 and the first spacer 22, and exposes an upper surface of the first sacrificial gate 23.

A second sacrificial gate 24 is formed on the second region II, and a spacer 22 is formed on a side wall of the second sacrificial gate 24. The interlayer insulating film 20 surrounds the second sacrificial gate 24 and the spacer 22, and exposes an upper surface of the second sacrificial gate 24.

The first sacrificial gate 23 and the second sacrificial gate 24 may be made of, for example, polysilicon, but are not limited thereto.

A source/drain region 15 is formed on at least one side of the first sacrificial gate 23 and the second sacrificial gate 24. The source/drain region 15 may be formed through an ion injection process, and is formed on the substrate 10.

Then, referring to FIGS. 5 and 7, the first and second sacrificial gates 23 and 24 are removed, and gate insulating films 40a and 45a are formed in the first and second trenches 26 and 27 (S200).

Before the gate insulating films 40a and 45a are formed, a first interface film 30 may be formed in the first trench 26, and a second interface film 35 may be formed in the second trench 27. The first and second interface films 30 and 35 may be formed by oxidizing an upper surface of the substrate 10, but are not limited thereto.

Then, the first gate insulating film 40a is formed in the first trench 26, and the second gate insulating film 45a is formed in the second trench 27. Specifically, the first gate insulating film 40a is conformally formed along an upper surface of the interlayer insulating film 20 and side walls and a bottom surface of the first trench 26. The second gate insulating film 45a is conformally formed along the upper surface of the interlayer insulating film 20 and side walls and a bottom surface of the second trench 27. The first gate insulating film 40a and the second gate insulating film 45a may be high-k films.

Then, a first etching prevention film 50a is formed on the first gate insulating film 40a in the first trench 26, and a second etching prevention film 55a is formed on the second gate insulating film 45a in the second trench 27. The first etching prevention film 50a may be conformally formed along the side walls and the bottom surface of the first trench 26, and the second etching prevention film 55a may be conformally formed along the side walls and the bottom surface of the second trench 27. The first etching prevention film 50a and the second etching prevention film 55a may extend onto the interlayer insulating film 20.

Then, DIT improvement films 60a and 65a for improving the DIT of the substrate 10 are formed (S300). Specifically, the first DIT improvement film 60a is formed on the first etching prevention film 50a in the first trench 26, and the second DIT improvement film 65a is formed on the second etching prevention film 55a in the second trench 27. The first DIT improvement film 60a may be conformally formed along the side walls and the bottom surface of the first trench 26, and the second DIT improvement film 65a may be conformally formed along the side walls and the bottom surface of the second trench 27. The first DIT improvement film 60a and the second DIT improvement film 65a may extend onto the interlayer insulating film 20. The DIT improvement films 60a and 65a may be Al alloy films.

Then, first conductivity type work function adjustment films 70a and 75a are formed on the DIT improvement films 50a and 55a, respectively (S400). Specifically, one of the first conductivity type work function adjustment films 70a is formed on the first DIT improvement film 60a in the first trench 26, and the other of the first conductivity type work function adjustment films 75a is formed on the second DIT improvement film 65a in the second trench 27. One of the first conductivity type work function adjustment films 70a may be conformally formed along the side walls and the bottom surface of the first trench 26, and the other of the first conductivity type work function adjustment films 75a may be conformally formed along the side walls and the bottom surface of the second trench 27. One of the first conductivity type work function adjustment films 70a and the other of the first conductivity type work function adjustment films 75a may extend onto the interlayer insulating film 20.

In some embodiments, the first conductivity type work function adjustment films 70a and 75a may be P-type work function adjustment films.

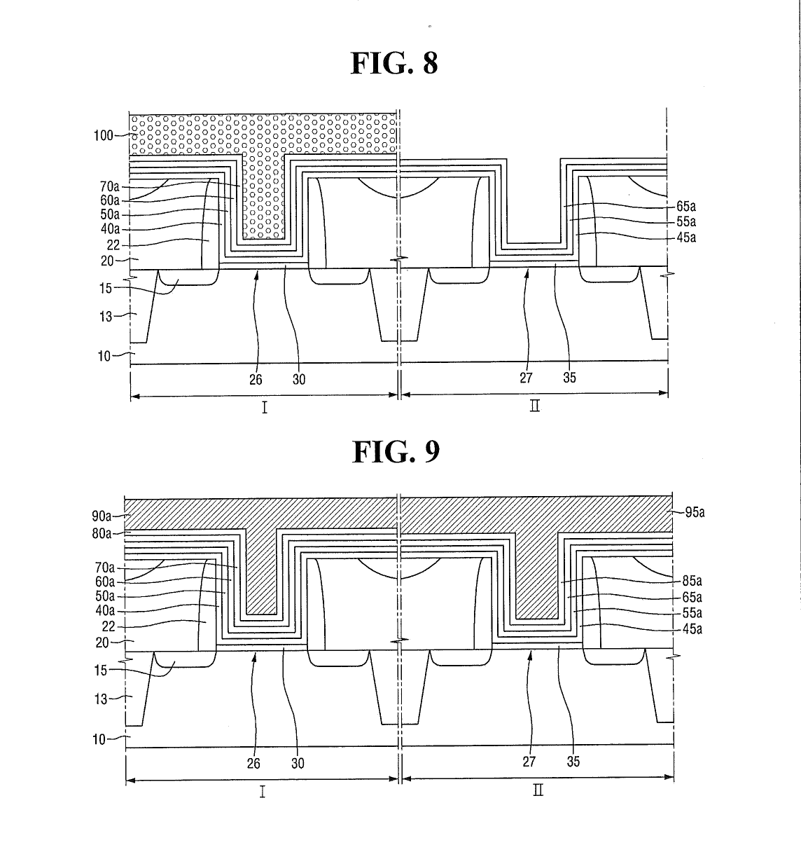

Referring to FIG. 8, the other of the first conductivity type work function adjustment films 75a on the second region II is removed. When the other of the first conductivity type work function adjustment films 75a is removed, the first region I may be covered by a first mask 100, and the other of the first conductivity type work function adjustment films 75a on the second region II may be removed. The other of the first conductivity type work function adjustment films 75a may be etched, for example, using at least one of wet etching and dry etching. In this case, the second DIT improvement film 65a may not be substantially etched. In other words, the second DIT improvement film 65a may resist etching, and thus can reduce or prevent damage of the second etching prevention film 55a and the gate insulating film 45a.

In some embodiments, although not illustrated in the drawings, the second DIT improvement film 65a may also be etched when the other of the first conductivity type work function adjustment films 75a is etched. That is, the other of the first conductivity type work function adjustment films 75a and the second DIT improvement film 65a in the second trench 27 may be etched together. Whether to remove the second DIT improvement film 65a may differ depending on methods used when the other of the first conductivity type work function adjustment films 75a is removed, materials included in the other of the first conductivity type work function adjustment films 75a and the second DIT improvement film 65a, or the etchant materials and/or processes that is/are used. Since the second etching prevention film 55a is formed even if the second DIT improvement film 65a is removed, the gate insulating film 45a may not removed, but may be protected against etching.

Then, referring to FIG. 9, second conductivity type work function adjustment films 80a and 85a are formed on the substrate 10. Specifically, one of the second conductivity type work function adjustment films 80a is formed on one of the first conductivity type work function adjustment films 70a in the first trench 26, and the other of the second conductivity type work function adjustment films 85a is formed on the second DIT improvement film 65a in the second trench 27. The second conductivity type work function adjustment film 80a may be conformally formed along the side walls and the bottom surface of the first trench 26, and the other second conductivity type work function adjustment film 85a may be conformally formed along the side walls and the bottom surface of the second trench 27. The second conductivity type work function adjustment films 80a, 85a may extend onto the interlayer insulating film 20. In some embodiments, the second conductivity type work function adjustment films 80a and 85a may be N-type work function adjustment films.

Then, a first gate metal 90a is formed on one of the second conductivity type work function adjustment films 80a in the first trench 26 and may fill the first trench 26, and a second gate metal 95a is formed on the other of the second conductivity type work function adjustment films 85a in the second trench 27 and may fill the second trench 27.

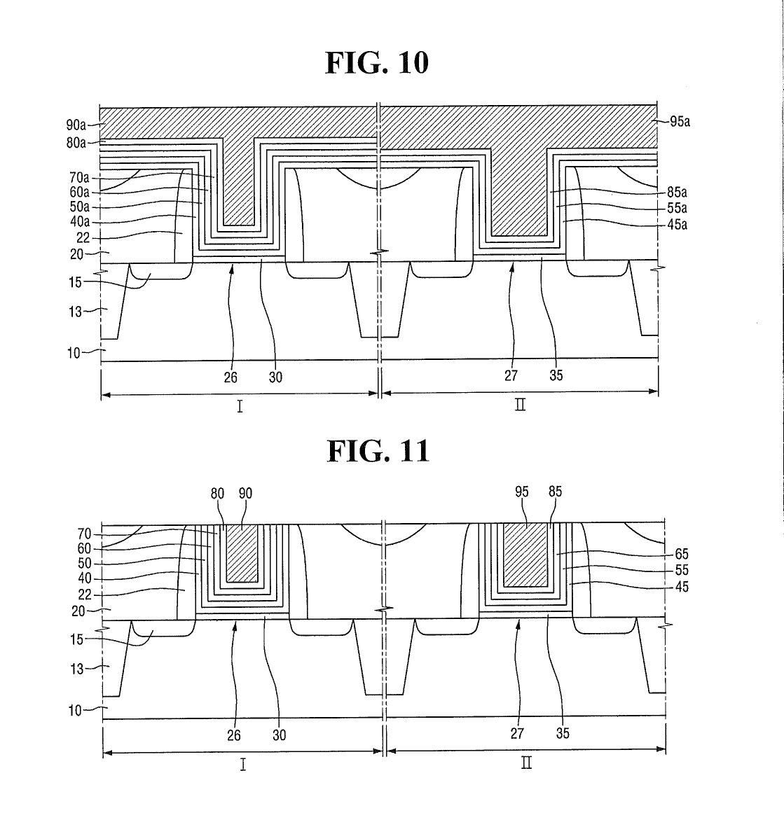

In some embodiments, if the second DIT improvement film 65a is also removed when the first conductivity type work function adjustment film 75a is removed, as illustrated in FIG. 10, the second conductivity type work function adjustment film 85a may be formed on the second etching prevention film 55a, and the second gate metal 95a may be formed on the second conductivity type work function adjustment film 85a.

Then, referring to FIG. 11, the interlayer insulating film 20 is exposed. In order to expose the interlayer insulating film 20, for example, a CMP (Chemical Mechanical Polishing) process may be performed, and through this, a semiconductor device as illustrated in FIG. 11 may be formed. The semiconductor device formed on the first region I in FIG. 11 may be precursor of a P-type transistor, and is the same as the semiconductor device according to the first embodiment of the present invention in FIG. 1. The second region II in FIG. 11 may be a precursor of an N-type transistor.

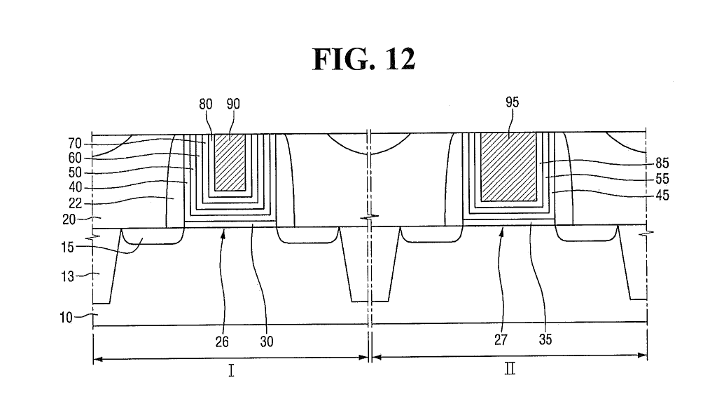

In some embodiments, if the second DIT improvement film 65a is also etched when the other of the first conductivity type work function adjustment films 75a is etched, as illustrated in FIG. 12, a semiconductor device in which the DIT improvement film 65 is not disposed on the second region II may be formed. The semiconductor device formed on the first region I in FIG. 12 may be a precursor to a P-type transistor, and is the same as the semiconductor device according to the first embodiment of the present invention in FIG. 1. The second region II in FIG. 12 may be a precursor to an N-type transistor.

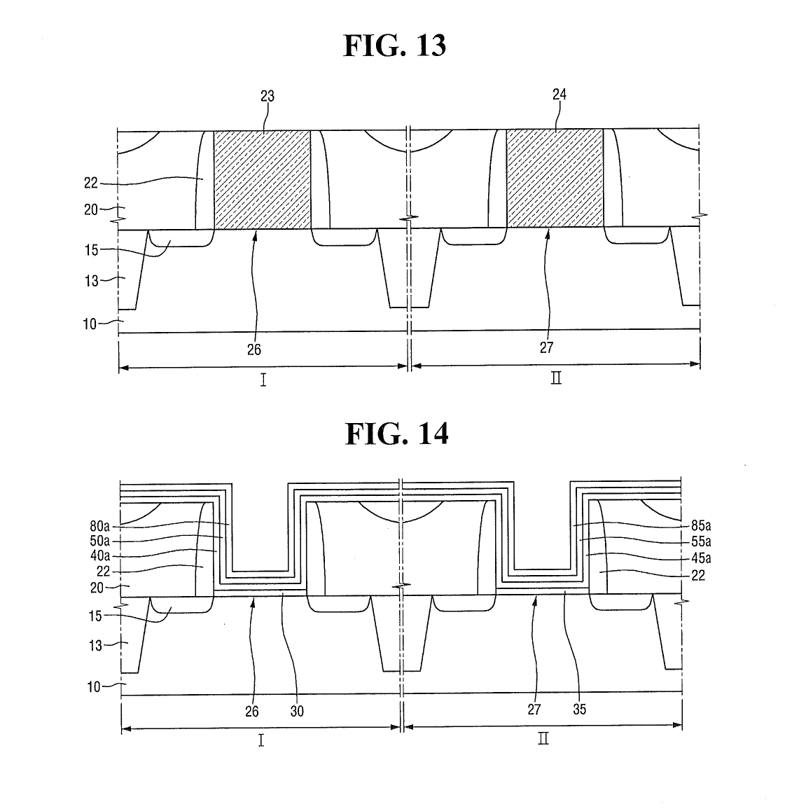

Referring to FIGS. 13 to 17, methods for fabricating a semiconductor device according to further embodiments of the present inventive concepts will be described. In the following description, explanation of features and processes that are unnecessarily duplicative of the previously described embodiments will be omitted.

FIGS. 13 to 17 are views of intermediate steps that illustrate methods for fabricating a semiconductor device according to further embodiments of the present inventive concepts.

First, referring to FIG. 13, an interlayer insulating film 20 that includes first and second trenches 26 and 27 is formed on a substrate 10. The substrate 10 includes a first region I and a second region II, and the first region I and the second region II may be separated from each other by an isolation film 13. For example, a PMOS transistor may be formed on the first region I of the substrate 10, and an NMOS transistor may be formed on the second region II of the substrate 10.

A first sacrificial gate 23 is formed on the first region I, and a first spacer 22 is formed on a side wall of the first sacrificial gate 23. The interlayer insulating film 20 surrounds the first sacrificial gate 23 and the first spacer 22, and exposes an upper surface of the first sacrificial gate 23.

A second sacrificial gate 24 is formed on the second region II, and a spacer 22 is formed on a side wall of the second sacrificial gate 24. The interlayer insulating film 20 surrounds the second sacrificial gate 24 and the spacer 22, and exposes an upper surface of the second sacrificial gate 24.

The first sacrificial gate 23 and the second sacrificial gate 24 may be made of, for example, polysilicon, but are not limited thereto.

A source/drain region 15 is formed on at least one side of the first sacrificial gate 23 and the second sacrificial gate 24. The source/drain region 15 may be formed through an ion injection process, and is formed on the substrate 10.

Then, referring to FIG. 14, the first and second sacrificial gates 23 and 24 are removed, and gate insulating films 40a and 45a, etching prevention films 50a and 55a, and second conductivity type work function adjustment films 80a and 85a are conformally formed in sequence along side walls and bottom surfaces of the first and second trenches 26 and 27 in the first and second trenches 26 and 27. Unlike the previously described methods, the second conductivity type work function adjustment films 80a and 85a are formed prior to forming the first conductivity type work function adjustment films (70a and 75a in FIG. 16).

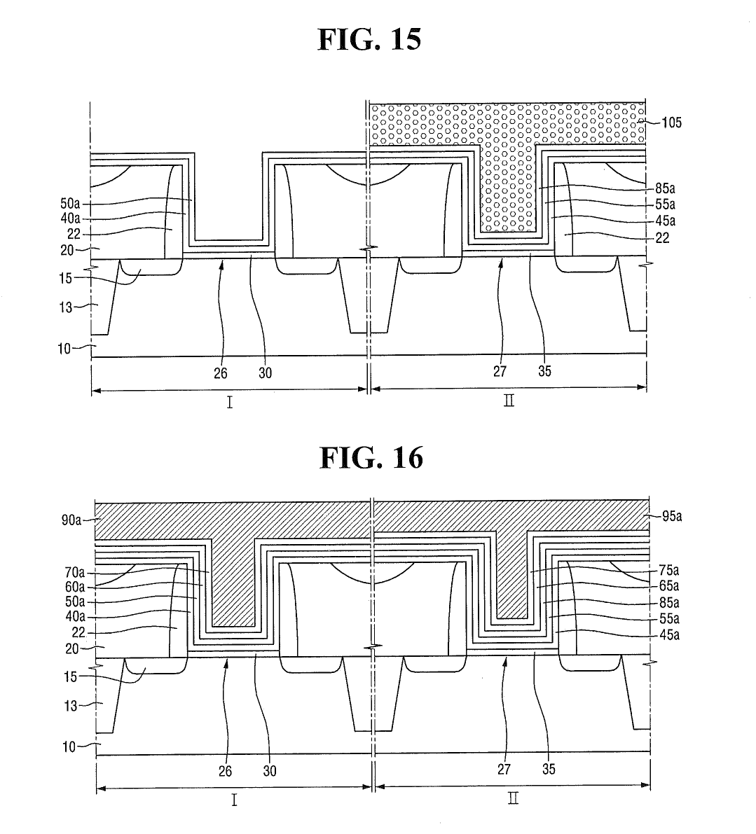

Then, referring to FIG. 15, the second region II is covered by a second mask 105, and one of the second conductivity type work function adjustment films 80a on the first region I is removed. At this time, the first etching prevention film 50a may protect the first gate insulating film 40a from being etched.

Then, referring to FIG. 16, the second mask 105 on the second region II is removed, and DIT improvement films 60a and 65a, the first conductivity type work function adjustment films 70a and 75a, and gate metals 90a and 95a are sequentially formed on the substrate 10. Specifically, the DIT improvement films 60a and 65a and the first conductivity type work function adjustment films 70a and 75a may be conformally formed along the side walls and the bottom surfaces of the first and second trenches 26 and 27, and the gate metals 90a and 95a may be formed to at least partially fill the first and second trenches 26 and 27.

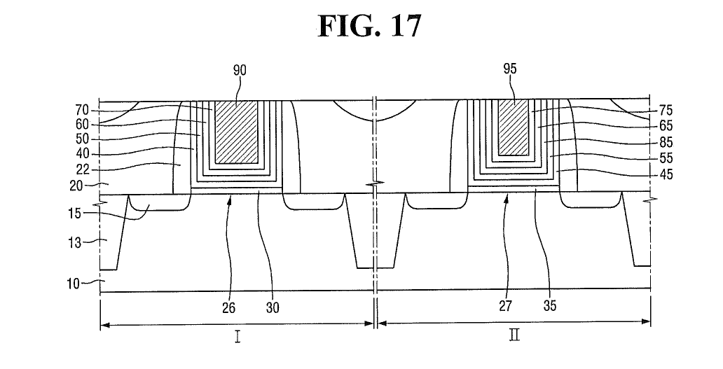

Then, referring to FIG. 17, the interlayer insulating film 20 is exposed. In order to expose the interlayer insulating film 20, for example, a CMP (Chemical Mechanical Polishing) process may be performed, and through this, a semiconductor device as illustrated in FIG. 17 may be formed. The semiconductor device formed on the first region I in FIG. 17 may be a P-type transistor later, and is the same as the semiconductor device according to the second embodiment of the present invention in FIG. 4. The second region II in FIG. 16 may be an N-type transistor later.

In methods for fabricating a semiconductor device illustrated in FIGS. 13-17, unlike the previously described methods, the second conductivity type work function adjustment film 80 is formed first, and then the first conductivity type work function adjustment film 70 is formed. Accordingly, only the first conductivity type work function adjustment film 70 exists on the first region I, and the second conductivity type work function adjustment film 80 does not exist on the first region I.

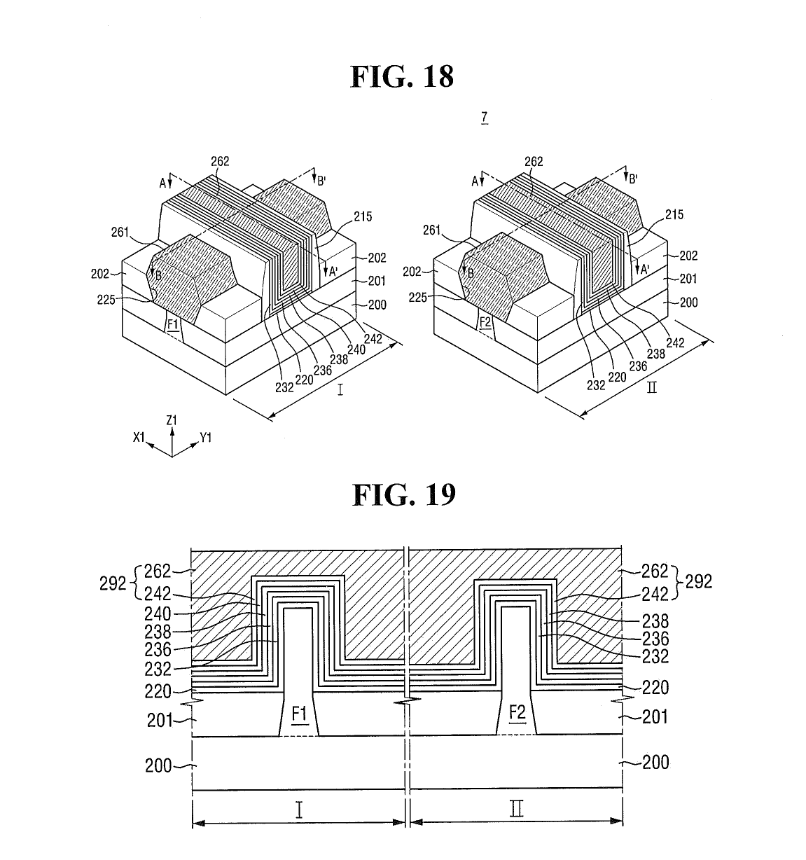

Referring to FIGS. 18 to 20, a semiconductor device according to still further embodiments of the present inventive concepts will be described. Explanation of the contents unnecessarily duplicative to those as described above will be omitted.

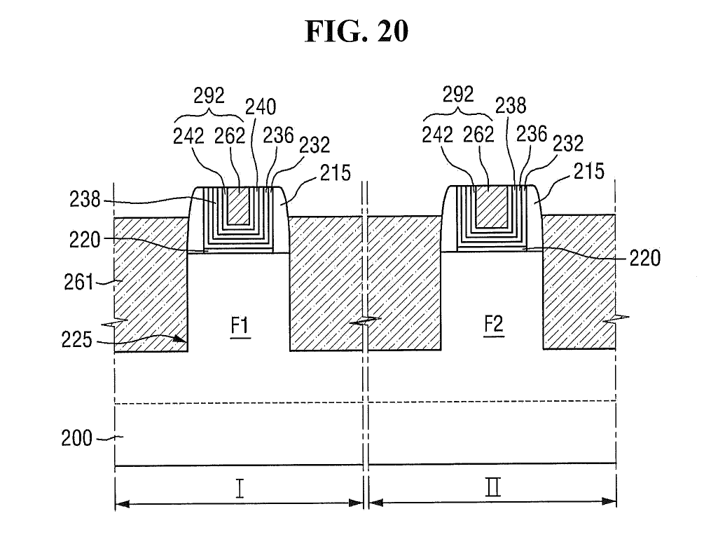

FIG. 18 is a view illustrating a semiconductor device according to further embodiments of the present inventive concepts. FIG. 19 is a cross-sectional view cut along line A-A′ in FIG. 18, and FIG. 20 is a cross-sectional view cut along line B-B′ in FIG. 18.

FIGS. 18 to 20 illustrate that a semiconductor device according to some embodiments of the present invention can have the form of a fin transistor FinFET, but the present invention is not limited thereto. If needed, any semiconductor device according to another embodiment that is not illustrated herein, for example, a semiconductor device according to the second embodiment of the present invention, may be applied to the fin transistor FinFET.

Referring to FIGS. 18 to 20, a semiconductor device 7 according to the third embodiment of the present invention may include fins F1 and F2, a gate electrode 292, a recess 225, and a source/drain region 261.

The fins F1 and F2 may include the first fin F1 formed on a first region I of a semiconductor substrate 200 and the second fin F2 formed on a second region II of the semiconductor substrate 200, and may extend long along a second direction Y1. Here, the fins F1 and F2 may be a part of the substrate 200, and may include an epitaxial layer grown from the substrate 200. An isolation film 201 may cover side surfaces of the fins F1 and F2.

A first transistor TR1 may be formed on the first fin F1, and a second transistor TR2 may be formed on the second fin F2. The first transistor TR1 may include an interface film 220, a gate insulating film 232, an etching prevention film 236, a DIT improvement film 238, a first conductivity type work function adjustment film 240, a second conductivity type work function adjustment film 242, and a gate metal 262, which are sequentially formed on the first fin F1.

The second transistor TR2 may include an interface film 220, a gate insulating film pattern 232, an etching prevention film 236, a DIT improvement film 238, a second conductivity type work function adjustment film 242, and a gate metal 262, which are sequentially formed on the second fin F2.

In this embodiment, the first conductivity type work function adjustment film 240 may exist only in the first transistor TR1, and thus operation characteristics of the first transistor TR1 and the second transistor TR2 may differ from each other. In the first transistor, the first conductivity type work function adjustment film 240 exists on a lower portion of the second conductivity type work function adjustment film 242, and thus only the first conductivity type work function adjustment film 240 exerts an influence on the operation characteristics of the first transistor TR1.

Further, since the DIT improvement film 238 is formed in the first transistor TR1, the DIT between the fin F1 and the interface film 220 is decreased, and thus the performance of the first transistor TR1 can be improved. As described above, the DIT improvement film 238 may have a thickness of 1 Å to 30 Å.

The gate electrode 292 is formed on the fins F1 and F2 to cross the fins F1 and F2. The gate electrode 292 may extend in a first direction X1. As illustrated, the gate electrode may include the second conductivity type work function adjustment film 242 and the gate metal 262.

The recess 225 may be formed in the fins F1 and F2 on both sides of the gate electrode 292. A side wall of the recess 225 is inclined, and the recess 225 is shaped to become wider as it goes far from the substrate 200. As illustrated in FIG. 18, the width of the recess 225 may be wider than the width of the fins F1 and F2.

The source/drain region 261 is formed in the recess 225. The source/drain region 261 may be in the form of an elevated source/drain. That is, an upper surface of the source/drain region 261 may be higher than a lower surface of the interlayer insulating film 202. Further, the source/drain region 261 and the gate electrode 292 may be insulated by a spacer 215.

In the case where the first transistor TR1 is a P-type transistor, the source/drain region 261 may include a compression stress material. For example, the compression stress material may be a material having a large lattice constant in comparison to Si, and may be, for example, SiGe. The compression stress material may apply compression stress to the first fin F1 to improve mobility of carriers of a channel region.

On the other hand, in the case where the first transistor TR1 is an N-type transistor, the source/drain region 261 may include the same material as the substrate 200 or a tension stress material. For example, if the substrate 200 includes Si, the source/drain region 261 may include Si or a material having a smaller lattice constant than Si (for example, SiC).

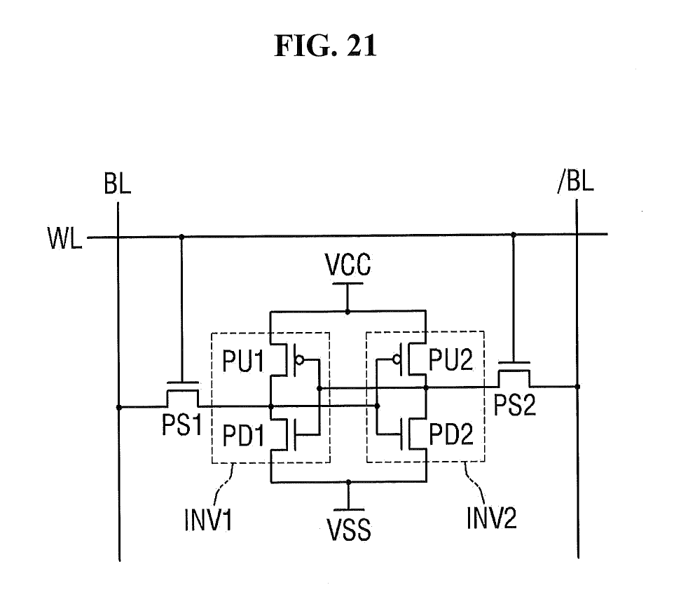

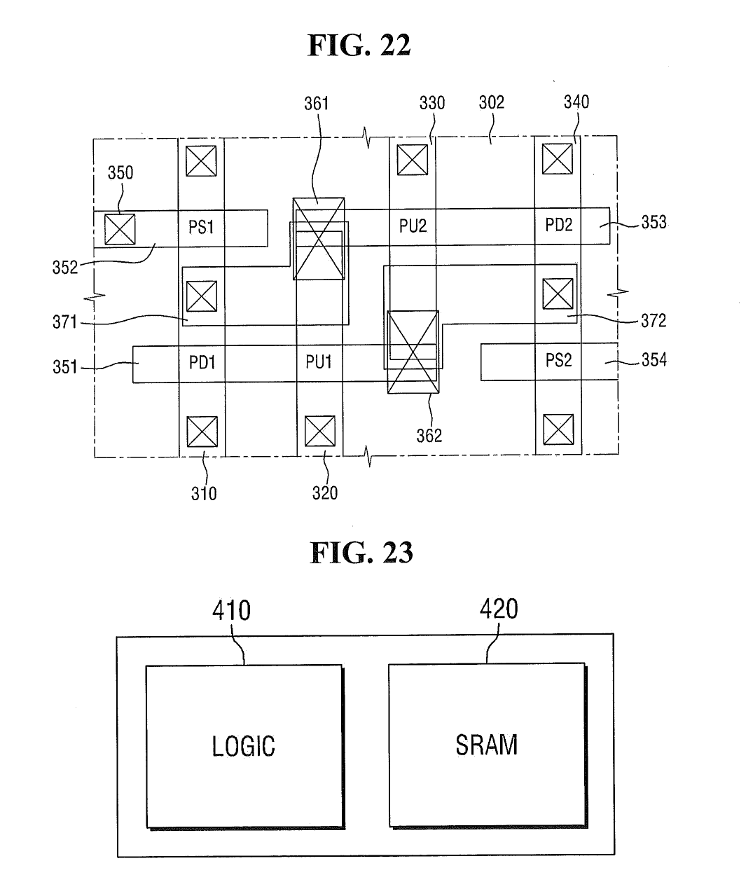

Referring to FIGS. 21 and 22, a semiconductor device according to a fourth embodiment of the present invention will be described. FIGS. 21 and 22 are a circuit diagram and a layout diagram explaining a semiconductor device according to a fourth embodiment of the present invention.

Referring to FIGS. 21 and 22, a semiconductor device according to the fourth embodiment of the present invention may include a pair of inverters INV1 and INV2 connected in parallel between a power supply node Vcc and a ground node Vss, a first path transistor PS1 and a second pass transistor PS2 connected to output nodes of the respective inverters INV1 and INV2. The first pass transistor PS1 and the second pass transistor PS2 may be connected to a bit line BL and a complementary bit line/BL, respectively. Gates of the first pass transistor PS1 and the second pass transistor PS2 may be connected to a word line WL.

The first inverter INV1 includes a first pull-up transistor PU1 and a first pull-down transistor PD1 which are connected in series, and the second inverter INV2 includes a second pull-up transistor PU2 and a second pull-down transistor PD2 which are connected in series. The first pull-up transistor PU1 and the second pull-up transistor PU2 may be PMOS transistors, and the first pull-down transistor PD1 and the second pull-down transistor PD2 may be NMOS transistors.

Further, the first inverter INV1 and the second inverter INV2 may constitute one latch circuit in a manner that an input node of the first inverter INV1 is connected to an output node of the second inverter INV2, and an input node of the second inverter INV2 is connected to an output node of the first inverter INV1.

Here, referring to FIGS. 21 and 22, a first active region 310, a second active region 320, a third active region 330, and a fourth active region 340, which are spaced apart from each other, are formed to extend long in one direction (for example, upper/lower direction in FIG. 22). The extending length of the second active region 320 and the third active region 330 may be shorter than the extending length of the first active region 310 and the fourth active region 340.

Further, a first gate electrode 351, a second gate electrode 352, a third gate electrode 353, and a fourth gate electrode 354 extend long in the other direction (for example, right/left direction in FIG. 22), and are formed to cross the first to fourth active regions 310 to 340. Specifically, the first gate electrode 351 may be formed to completely cross the first active region 310 and the second active region 320 and to overlap a part of a vertical end of the third active region 330. The third gate electrode 353 may be formed to completely cross the fourth active region 340 and the third active region 330 and to overlap a part of a vertical end of the second active region 320. The second gate electrode 352 and the fourth gate electrode 354 may be formed to cross the first active region 310 and the fourth active region 340, respectively.

As illustrated, the first pull-up transistor PU1 is defined around a region where the first gate electrode 351 and the second active region 320 cross each other, the first pull-down transistor PD1 is defined around a region where the first gate electrode 351 and the first active region 310 cross each other, and the first pass transistor PS1 is defined around a region where the second gate electrode 352 and the first active region 310 cross each other. The second pull-up transistor PU2 is defined around a region where the third gate electrode 353 and the third active region 330 cross each other, the second pull-down transistor PD2 is defined around a region where the third gate electrode 353 and the fourth active region 340 cross each other, and the second pass transistor PS2 is defined around a region where the fourth gate electrode 354 and the fourth active region 340 cross each other.

Although not clearly illustrated, the source/drain may be formed on both sides of a region where the first to fourth gate electrodes 351 to 354 and the first to fourth active regions 310, 320, 330, and 340 cross each other.

Further, a plurality of contacts 350 may be formed.

In addition, a shared contact 361 simultaneously connects the second active region 320, the third gate electrode 353, and a wiring 371. A shared contact 362 simultaneously connects the third active region 330, the first gate electrode 351, and a wiring 372.

For example, the first pull-up transistor PU1 and the second pull-up transistor PU2 may have a configuration explained using at least one of the first regions I in FIGS. 1, 4, and 18, and the first pull-down transistor PD1, the first pass transistor PS1, the second pull-down transistor PD2, and the second pass transistor PS2 may have a configuration explained using at least one of the second region II in FIGS. 11, 12, and 17 and the second region II in FIG. 18.

Referring to FIG. 23, a semiconductor device according to a fifth embodiment of the present invention will be described. FIG. 23 is a view explaining a semiconductor device according to a fifth embodiment of the present invention.

Referring to FIG. 23, the semiconductor device according to the fifth embodiment of the present invention may include a logic region 410 and an SRAM region 420.

For example, the structure as explained using FIGS. 1, 4, 11, 12, 17, and 18 may be applied to the logic region 410, but may not be applied to the SRAM region 420.

Further, the structure as explained using FIGS. 1, 4, 11, 12, 17, and 18 may be applied to both the logic region 410 and the SRAM region 420.

Further, the structure as explained using FIGS. 1, 4, 11, 12, 17, and 18 may be applied to the SRAM region 420, but may not be applied to the logic region 410.

Although FIG. 23 exemplarily illustrates the logic region 410 and the SRAM region 420, the present invention is not limited thereto. For example, the present invention can be applied to the logic region 410 and a region where another memory is formed (for example, DRAM, MRAM, RRAM, or PRAM).

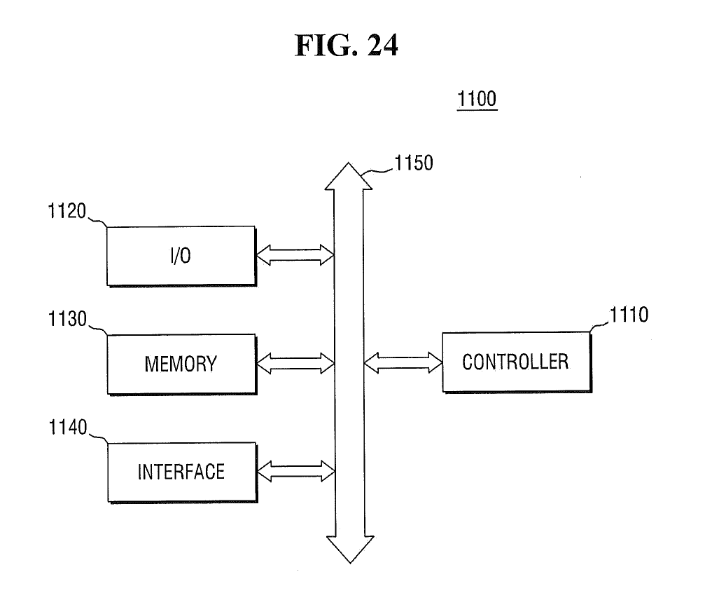

FIG. 24 is a block diagram of an electronic system including a semiconductor device according to some embodiments of the present invention.

Referring to FIG. 24, an electronic system 1100 according to an embodiment of the present invention may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver. Although not illustrated, the electronic system 1100 may further include a high-speed DRAM and/or SRAM as an operating memory for improving the operation of the controller 1110. A fin field-effect transistor according to embodiments of the present invention may be provided inside the memory 1130 or may be provided as a part of the controller 1110 and the I/O device 1120.

The electronic system 1100 may be applied to a PDA (Personal Digital Assistant), a portable computer, a web tablet, a wireless phone, a mobile phone, a digital music player, a memory card, or all electronic devices that can transmit and/or receive information in wireless environments.

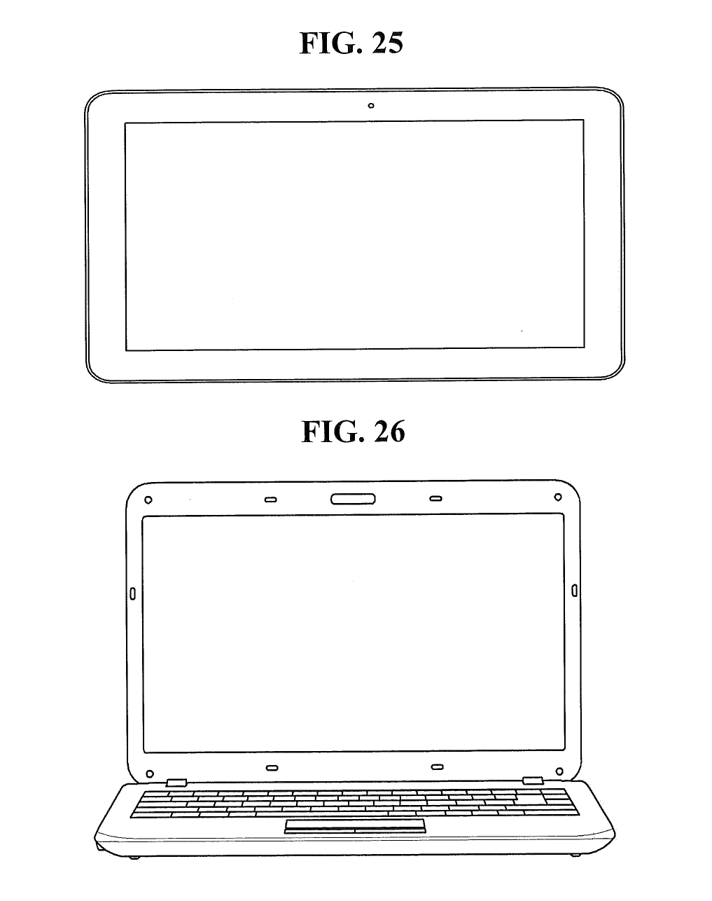

FIGS. 25 and 26 are exemplary views of a semiconductor system to which the semiconductor device according to some embodiments of the present invention can be applied. FIG. 25 illustrates a tablet PC, and FIG. 26 illustrates a notebook PC. At least one of the semiconductor devices according to the first and second embodiments of the present invention may be used in the tablet PC or the notebook PC. It is apparent to those of skilled in the art that the semiconductor device according to some embodiments of the present invention can be applied even to other integrated circuit devices that have not been exemplified.

A PMOS transistor according to some embodiments can have a reduced DIT (Density of Interface Trap). Further, some embodiments provide methods for fabricating a PMOS semiconductor device having improved DIT characteristics.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A semiconductor device comprising:
an insulating film on a substrate, the insulating film including a trench therein;
a gate insulating film in the trench;
a DIT (Density of Interface Trap) improvement film on the gate insulating film, the DIT improvement film improving a DIT of the substrate; and
a first conductivity type work function adjustment film on the DIT improvement film.

2. The semiconductor device of claim 1, wherein the first conductivity type is P-type.

3. The semiconductor device of claim 2, wherein the first conductivity type work function adjustment film comprises at least one of Mo, Pd, Ru, Pt, TiN, WN, TaN, Ir, TaC, RuN, and MoN.

4. The semiconductor device of claim 1, wherein the DIT improvement film comprises an Al alloy film.

5. The semiconductor device of claim 4, wherein the DIT improvement film comprises a TiAlC film.

6. The semiconductor device of claim 1, wherein the DIT improvement film has a thickness of 1 Å to 30 Å.

7. The semiconductor device of claim 1, further comprising an etching prevention film between the gate insulating film and the DIT improvement film,
wherein the etching prevention film has a thickness of 1 Å to 30 Å.

8. The semiconductor device of claim 1, further comprising a second conductivity type work function adjustment film on the first conductivity type work function adjustment film, wherein the second conductivity type is different from the first conductivity type.

9. The semiconductor device of claim 8, wherein the second conductivity type is N-type.

10. The semiconductor device of claim 9, wherein the second conductivity type work function adjustment film and the DIT improvement film comprise a same material.

11. A method of forming a semiconductor device, the method comprising:
forming an insulating film that includes first and second trenches on a substrate;
forming a gate insulating film in the first and second trenches;
forming a Density of Interface Traps (DIT) improvement film that improves a DIT of the substrate on the gate insulating film; and
forming a first conductivity type work function adjustment film on the DIT improvement film.

12. The method of forming a semiconductor device of claim 11, further comprising removing the first conductivity type work function adjustment film from the second trench after forming the first conductivity type work function adjustment film, and forming a second conductivity type work function adjustment film in the first and second trenches, wherein the second conductivity type is different from the first conductivity type.

13. The method of forming a semiconductor device of claim 12, wherein when the first conductivity type work function adjustment film is removed, the DIT improvement film in the second trench is protected from removal.

14. The method of forming a semiconductor device of claim 12, wherein the removing the first conductivity type work function adjustment film further comprises selectively removing the DIT improvement film in the second trench.

15. The method of forming a semiconductor device of claim 11, further comprising forming an etching prevention film on the gate insulating film after forming the gate insulating film, forming a second conductivity type work function adjustment film on the etching prevention film, and selectively removing the second conductivity type work function adjustment film from the first trench.

16. A semiconductor device comprising:
a substrate;
an insulating film on the substrate, the insulating film including first and second trenches therein;
gate insulating films in the first and second trenches;
a first conductivity type work function adjustment film on the gate insulating films in the first and second trenches;
a second conductivity type work function adjustment film in the first trench; and
DIT (Density of Interface Trap) improvement films on the gate insulating films, the DIT improvement films improving a DIT of the substrate,
wherein the second trench is free of the second conductivity type work function adjustment film, wherein the second conductivity type is different from the first conductivity type, and wherein the first conductivity type work function adjustment film is on the DIT improvement films in the first and second trenches.
